(19) United States
(12) Patent Application Publication
(10) Pub. No.: US 2015/0336234 A1
(43) Pub. Date: Nov. 26, 2015

(54) METHOD FOR PRODUCING LAYERED POLISHING PADS

(71) Applicant: TOYO TIRE & RUBBER CO., LTD., Osaka-shi, Osaka (JP)

(72) Inventor: Tsuyoshi KIMURA, Osaka (JP)

(21) Appl. No.: 14/652,774

(22) PCT Filed: Oct. 18, 2013
(86) PCT No.: PCT/JP2013/078294

§ 371 Date: Jun. 16, 2015

(30) Foreign Application Priority Data
Dec. 26, 2012 (JP) 2012-283201

(51) Int. Cl. B24B 37/26; H01L 21/306

(52) U.S. Cl. CPC B24B 37/26; H01L 21/30625

(57) ABSTRACT

The present invention relates to a method for producing a layered circular polishing pad, comprising steps of forming, in a circular polishing sheet, concentric grooves and an outer circumferential region having a width of ½ or more of a groove pitch of the concentric grooves; and bonding the circular polishing sheet and a supporting layer to each other with a bonding member interposed therebetween to produce a layered polishing sheet. According to the present invention, it is possible to provide a method for producing a layered circular polishing pad in which the polishing layer and the supporting layer are not easily peeled from each other.

### TECHNICAL FIELD

The present invention relates to a method for producing a layered polishing pad which performs planarization of materials requiring a high surface planarity such as optical materials including a lens and a reflecting mirror, a silicon wafer, a glass substrate or aluminum substrate for a hard disc, and a product of general metal polishing.

### BACKGROUND ART

When a semiconductor device is produced, for example, the following steps are performed: the step of forming a conductive film on a surface of a wafer, and subjecting the resultant to photolithography, etching and other processings to form an interconnection layer; and the step of forming an interlayer dielectric onto the interconnection layer. These steps result in the generation of irregularities made of conductor such as metal, or insulator on the wafer surface. In recent years, interconnections have been becoming finer and turning into a higher-level multi-layered form for the purpose of making the integration degree of semiconductor integrated circuits higher. With this tendency, a technique for planarizing irregularities of wafer surfaces has been become important.

Conventionally, a polishing pad used to attain polishing with a high precision is generally a polyurethane foam sheet. However, the polyurethane foam sheet is short in cushion performance although the sheet is excellent in local planarizing power. It is therefore difficult to give an even pressure to the whole surface of a wafer. Thus, usually, a cushion layer is separately laid onto the rear surface of a polyurethane foam sheet, and this laminate is used as a layered polishing pad for polishing (Patent Document 1).

A semiconductor wafer polishing pad has also been developed in which a polishing layer, a second layer larger in elastic modulus than the polishing layer, and a third layer lower in elastic modulus than the second layer are laminated in this order (Patent Document 2).

### PRIOR ART DOCUMENT

### Patent Documents

Patent Document 1: JP-A-2003-53657

Patent Document 2: Japanese Patent No. 3788729

### SUMMARY OF THE INVENTION

### Problems to be Solved by the Invention

However, a layered polishing pad which has concentric grooves for holding and renewing a slurry and which is produced by conventional production method has a problem that the polishing layer and the supporting layer, such as a cushion layer, are easily peeled from each other.

In light of the problem, the present invention has been made, and an object thereof is to provide a method for producing a polishing pad in which the polishing layer and the supporting layer are not easily peeled from each other.

### Means for Solving the Problems

The present invention relates to a method for producing a layered circular polishing pad, comprising steps of forming, in a circular polishing sheet, concentric grooves and an outer circumferential region having a width of ½ or more of a groove pitch of the concentric grooves; and bonding the circular polishing sheet and a supporting layer to each other with a bonding member interposed therebetween to produce a layered polishing sheet.

The present invention also relates to a layered circular polishing pad, comprising a circular polishing layer and a supporting layer laminated over each other with an adhesive member interposed therebetween, wherein concentric grooves are formed in the polishing layer, the polishing layer has an outer circumferential region in which the concentric grooves are not formed, and the outer circumferential region has a width of ½ or more of a groove pitch of the concentric grooves.

The present invention also relates to a method for producing a semiconductor device, comprising a step of using the above-mentioned layered circular polishing pad to polish a surface of a semiconductor wafer.

### Effect of the Invention

The method for producing a layered circular polishing pad of the present invention includes the step of forming, in a circular polishing sheet, concentric grooves and an outer circumferential region having a width of ½ or more of a groove pitch of the concentric grooves. Accordingly, in the step of bonding the circular polishing sheet and a supporting layer to each other with a bonding member interposed therebetween to produce a layered polishing sheet, at the time of bonding the circular polishing sheet and the supporting layer to each other while pressuring this sheet and this layer, the pressure can be sufficiently applied to the circular polishing sheet and the supporting layer from any position of each of these members to the end thereof by aid of the outer circumferential region, the width of which is ½ or more of the groove pitch of the concentric grooves. Thus, the layered circular polishing pad can ensure, from any position thereof to the end thereof, a sufficient bonding strength. The present invention can therefore provide a method for producing a layered circular polishing pad in which the polishing layer and the supporting layer are not easily peeled from each other.

In the layered circular polishing pad of the present invention, the polishing layer has an outer circumferential region in which the concentric grooves are not formed, and further the width of the outer circumferential region is ½ or more of the groove pitch of the concentric grooves; thus, when the layered circular polishing pad is attached to, for example, a platen of a polishing apparatus, pressure can be sufficiently applied to the layered circular polishing pad from any position thereof to an end thereof. For this reason, the layered polishing pad can ensure, from any position thereof to the end thereof, a sufficient bonding strength. The present invention can therefore provide a layered polishing pad which is not easily peeled from the polishing apparatus.

### BRIEF DESCRIPTION OF THE DRAWINGS

FIG. 1 is a schematic structural view illustrating an example of a polishing apparatus used in CMP polishing.

FIG. 2 is a schematic view illustrating a groove shape of a polishing layer.

FIG. 3 is a schematic view illustrating the groove shape of the polishing layer.

### MODE FOR CARRYING OUT THE INVENTION

The method for producing a layered circular polishing pad of the present invention includes steps of forming, in a circular polishing sheet, concentric grooves and an outer circumferential region having a width of ½ or more of a groove pitch of the concentric grooves, and bonding the circular polishing sheet and a supporting layer to each other with a bonding member interposed therebetween to produce a layered polishing sheet.

### <Preparation of Circular Polishing Sheet>

The circular polishing sheet is not particularly limited as far as the sheet is a foam having fine cells. Examples thereof include any one of the following, and any mixture of two or more thereof: polyurethane resins, polyester resins, polyamide resins, acrylic resins, polycarbonate resins, halogen-containing resins (such as polyvinyl chloride, polytetrafluoroethylene, and polyvinylidene fluoride), polystyrenes, olefin-based resins (such as polyethylene and polypropylene), epoxy resins, and photosensitive resins. Polyurethane resins are excellent in abrasion resistance, and can be obtained as polymers having desired properties by changing the raw material composition thereof variously; thus, the resins are particularly preferred as a material for forming the polishing layer. Hereinafter, a description will be made about polyurethane resins as a typical example of the foam.

The polyurethane resin is made from an isocyanate component, a polyol component (a high-molecular-weight polyol or a low-molecular-weight polyol), and a chain extender.

As the isocyanate component, such a compound known in the field of polyurethane is usable without any particular limitation. Examples of the isocyanate component include aromatic diisocyanates such as 2,4-toluene diisocyanate, 2,6-toluene diisocyanate, 2,2′-diphenylmethane diisocyanate, 2,4′-diphenylmethane diisocyanate, 4,4′-diphenylmethane diisocyanate, 1,5-naphthalene diisocyanate, p-phenylene diisocyanate, m-phenylene diisocyanate, p-xylylene diisocyanate, and m-xylylene diisocyanate; aliphatic diisocyanates such as ethylene diisocyanate, 2,2,4-trimethylhexamethylene diisocyanate, and 1,6-hexamethylene diisocyanate; and alicyclic diisocyanates such as 1,4-cyclohexane diisocyanate, 4,4′-dicyclohexylmethane diisocyanate, isophorone diisocyanate, and norbornane diisocyanate. These may be used alone, or in the form of any mixture of two or more thereof.

The high-molecular-weight polyol may be one used ordinarily in the technical field of polyurethane. Examples of the high-molecular-weight polyol include polyether polyols, typical examples thereof being polytetramethylene ether glycol and polyethylene glycol; polyester polyols, a typical example thereof being polybutylene adipate; polyester-polycarbonate polyols, examples thereof including reaction products of a polyester glycol such as polycaprolactone polyol or polycaprolactone, and an alkylene carbonate; polyester-polycarbonate polyols obtained by allowing ethylene carbonate to react with a polyhydric alcohol, and next allowing the resultant reaction mixture to react with an organic dicarboxylic acid; and polycarbonate polyols obtained by a transesterification reaction between a polyhydroxyl compound and an aryl carbonate. These compounds may be used alone or in any combination of two or more thereof.

Besides the high-molecular-weight polyol, a low-molecular-weight polyol is together usable as the polyol component. Examples thereof include ethylene glycol, 1,2-propylene glycol, 1,3-propylene glycol, 1,2-butanediol, 1,3-butanediol, 1,4-butanediol, 2,3-butanediol, 1,6-hexanediol, neopentyl glycol, 1,4-cyclohexanedimethanol, 3-methyl-1,5-pentanediol, diethylene glycol, triethylene glycol, 1,4-bis(2-hydroxyethoxy)benzene, trimethylolpropane, glycerin, 1,2,6-hexanetriol, pentaerythritol, tetramethylolcyclohexane, methylglycoside, sorbitol, mannitol, dulcitol, sucrose, 2,2,6,6-tetrakis(hydroxymethyl)cyclohexanol, diethanolamine, N-methyldiethanolamine, and triethanolamine. A low-molecular-weight polyamine is together usable. Examples thereof include ethylenediamine, tolylenediamine, diphenylmethanediamine, and diethylenetriamine. An alcoholamine is together usable. Examples thereof include monoethanolamine, 2-(2-aminoethylamino)ethanol, and monopropanolamine. The low-molecular-weight polyols, the low-molecular-weight polyamines, and the others may be used alone or in any combination of two or more thereof. The blend amounts of the low-molecular-weight polyols, the low-molecular-weight polyamines, and the others are not particularly limited, and are appropriately determined in accordance with properties required for the polishing pad (polishing layer) to be produced.

When the polyurethane foam is produced by a prepolymer method, a chain extender is used for curing a prepolymer. The chain extender is an organic compound having at least two or more active hydrogen groups. Examples of the active hydrogen group include a hydroxyl group, a primary or secondary amino group, and a thiol group (SH). Specific examples of the extender include polyamines such as 4,4′-methylenebis(o-chloroaniline) (MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethyleneoxide-di-p-aminobenzoate, 4,4′-diamino-3,3′,5,5′-tetramethyldiphenylmethane, 4,4′-diamino-3,3′-diisopropyl-5,5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 3,3′-diethyl-4,4′-diaminodiphenylmethane, m-xylylenediamine, N,N′-di-sec-butyl-p-phenylenediamine, m-phenylenediamine, and p-xylylenediamine; and the low-molecular-weight polyols described above; and the low-molecular-weight polyamines described above. These may be used alone or in the form of a mixture of two or more thereof.

The ratio between the isocyanate component, the polyol component and the chain extender may be variously changed in accordance with the respective molecular weights thereof, desired properties of the resultant polishing pad, and others. In order to yield a polishing pad having desired polishing properties, the ratio of the number of isocyanate groups of the isocyanate component to the total number of active hydrogen groups (hydroxyl groups+amino groups) of the polyol component and the chain extender is from 0.80 to 1.20, more preferably from 0.99 to 1.15. If the number of the isocyanate groups is out of this range, the polyurethane foam is insufficiently cured to obtain neither a required specific gravity nor hardness. Thus, the polishing layer tends to be deteriorated in polishing properties.

The polyurethane foam may be produced by an application of a known urethanation technique such as a melting method or solution method. The polyurethane foam is produced preferably by the melting method when costs, working environment and others are considered.

The production of the polyurethane foam may be attained by either a prepolymer method or a one shot method. Preferred is a prepolymer method in which an isocyanate-terminated prepolymer is synthesized from an isocyanate component and a polyol component in advance, and then a chain extender is allowed to react with this prepolymer since physical properties of the resultant polyurethane resin are excellent.

Examples of the method for producing the polyurethane foam include a method of adding hollow beads, a mechanically foaming method, and a chemically foaming method.

In particular, preferred is a mechanically foaming method using a silicon-containing surfactant, which is a copolymer of a polyalkylsiloxane and a polyether and has no active hydrogen group.

Thereto may be optionally added a stabilizer such as an antioxidant, a lubricant, a pigment, a filler, an antistatic agent, and any other additive.

The polyurethane foam may be of an independent cell type or of a continuous cell type.

The production of the polyurethane foam may be in a batch system where each component is weighed, charged into a vessel and stirred, or in a continuous production system where each component and a non-reactive gas are continuously supplied into, and stirred in a stirring apparatus and the cell dispersion liquid is transferred to produce molded articles.

The production of the polyurethane foam may be in a manner of putting, into a reactor, a prepolymer which is a raw material of the polyurethane foam, charging a chain extender thereinto, stirring these components, casting the stirred components into a mold having a predetermined size to produce a block, and then using a slicer like a planer or a band saw to slice the block; or of making, at the stage of the casting, the stirred components into a thin sheet form. The polyurethane foam may be directly yielded into a sheet form by dissolving the resin which is a raw material, and then extruding the dissolved resin through a T-die.

The thickness of the circular polishing sheet is not particularly limited, and is usually from about 0.8 to 4 mm, preferably from 1.2 to 2.5 mm.

The polyurethane foam has an average cell diameter of preferably from 30 to 80 μm, more preferably from 30 to 60 μm. If the average cell diameter is out of this range, a polishing rate tends to be lowered or the planarity (flatness) of a material to be polished after polishing tends to be reduced.

The polyurethane foam has a specific gravity of preferably from 0.5 to 1.3. If the specific gravity is less than 0.5, the polishing layer tends to be lowered in surface strength or the planarity of a material to be polished tends to be reduced. If the specific gravity is more than 1.3, the number of the cells in the polishing layer surface is small so that the polishing rate tends to be lowered although the planarity is good.

The polyurethane foam has a hardness of preferably from 40 to 75 degrees according to an Asker D hardness meter. If the Asker D hardness is less than 40 degrees, the planarity of a material to be polished tends to be reduced. If the Asker D hardness is more than 75 degrees, uniformity (evenness) of a material to be polished tends to be reduced although the planarity is good.

<Step of Forming, in Circular Polishing Sheet, Concentric Grooves and Outer Circumferential Region Having Width of ½ or More of Groove Pitch of Concentric Grooves>

A method for forming concentric grooves in the circular polishing sheet is not particularly limited, and examples of the method include a method of using a jig, such as a bite, having a predetermined size to cut the sheet mechanically; a method of casting a resin into a mold having a predetermined surface shape, and curing the resin to form the grooves; a method of using a press plate having a predetermined surface shape to press a resin, thereby making the grooves; a method of using photolithography to make the grooves; a method of using a printing method to form the grooves; and a method of forming the grooves using laser light, for example, carbon dioxide laser.

Hereinafter, with reference to the drawings, a description will be made about the concentric grooves and the outer circumferential region having a width of more than ½ of the groove pitch of the concentric grooves, the grooves and the region being made in this step.

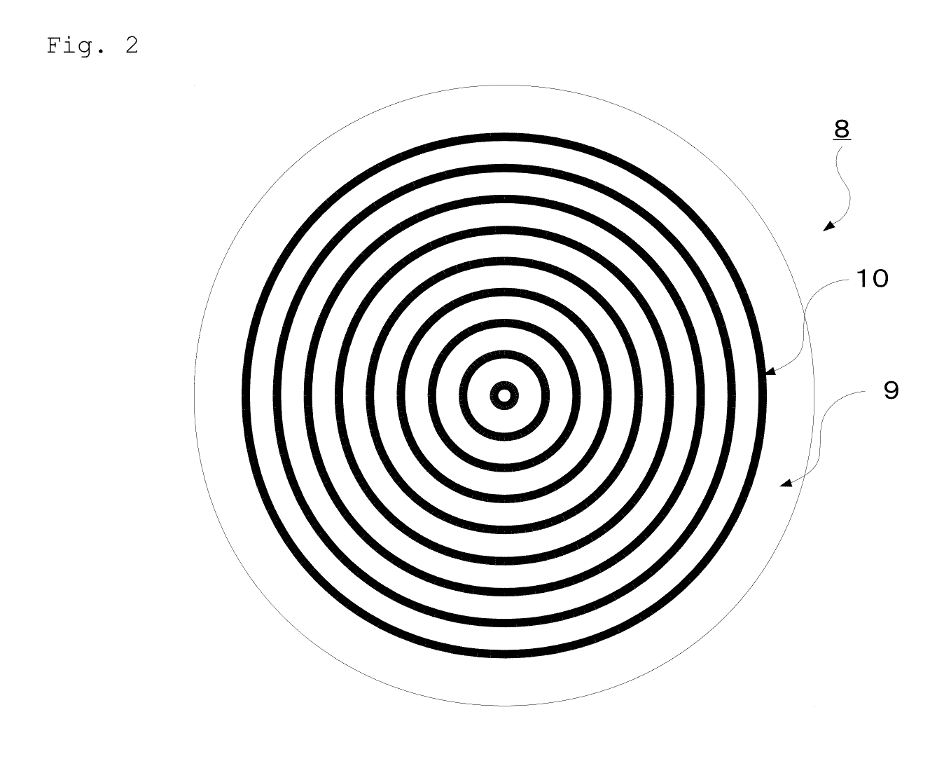

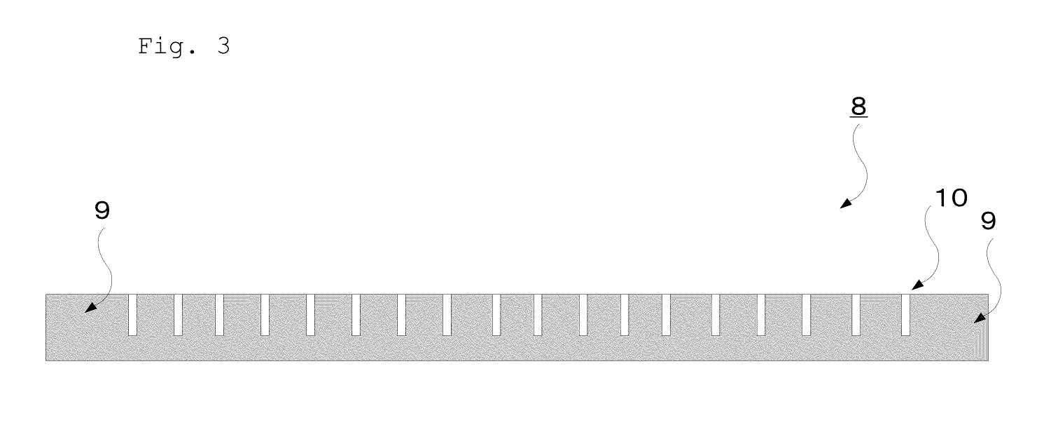

FIGS. 2 and 3 are schematic structural views of a circular polishing sheet having concentric grooves and an outer circumferential region having a width of more than ½ of a groove pitch of the concentric grooves. As illustrated in FIG. 2, a polishing surface contacting a material to be polished when a circular polishing sheet 8 is used as a polishing layer of a polishing pad has concentric grooves (concave portions) 10 in which a slurry is to be held and renewed. The polishing layer has, in the polishing surface thereof, the concentric grooves, whereby this layer can effectively hold and renew the slurry.

Moreover, the polishing layer adsorbs the material to be polished, whereby the material to be polished can be prevented from being broken.

The groove width, groove depth and groove pitch of the grooves 10 are not particularly limited. Usually, the groove width is from about 0.1 to 5 mm, the groove depth is from about 0.1 to 2 mm, and the groove pitch is from about 0.8 to 5.0 mm, preferably from 1.5 to 4.0 mm. In the present embodiment, the width of an outer circumferential region 9 of the circular polishing sheet 8 is ½ or more of the groove pitch of the concentric grooves, preferably equal to or more than the groove pitch, more preferably more than the groove pitch. If the width of the outermost circumferential region 9 of the circular polishing sheet 8 in the present embodiment is less than ½ of the groove pitch of the concentric grooves 10, the outermost circumferential region easily deforms. Thus, a pressure easily disperses which is applied when the polishing sheet and a supporting layer are bonded to each other while pressurized and/or when the polishing pad is attached to a platen. It is therefore difficult to apply a pressure sufficiently to the circular polishing sheet and the supporting layer from any position thereof to respective ends thereof. The peak of the outermost circumferential region 9 of the circular polishing sheet 8 in the present embodiment is positioned on the same plane as the respective peaks of convex portions between the concentric grooves are positioned. The groove pitch of the grooves 10 is generally regular. However, the groove pitch, the groove width, the groove depth, etc. may be varied in accordance with individual ranges of the sheet in order to make the slurry holding/renewing performances desirable. When the groove pitch, the groove width, the groove depth, etc. are varied in accordance with the individual ranges, the width of the outermost circumferential region 9 is ½ or more of the groove pitch nearest to the outermost circumferential region 9, preferably equal to or more than the groove pitch, even more preferably more than the groove pitch. The upper limit of the width of the outermost circumferential region 9 is not particularly limited, and is preferably 2 times or less the groove pitch of the concentric grooves 10 so as not to damage the slurry holding/renewing effect of the grooves 10.

The width of the outermost circumferential region 9 is preferably made larger than the groove depth of the groove adjacent to the region in order to apply a pressure sufficiently to the polishing sheet and the supporting layer from any position thereof to respective ends thereof when the polishing sheet and the supporting layer are bonded to each other while pressurized, and in order to apply a pressure sufficiently from any position of the polishing pad to the end thereof when the polishing pad is attached to a platen.

<Step of Bonding Circular Polishing Sheet and Supporting Layer to Each Other with Bonding Member Interposed Therebetween to Produce Layered Polishing Sheet>

### <Supporting Layer>

The supporting layer is a layer for compensating for properties of the polishing layer. The supporting layer may be a layer lower in elastic modulus than the polishing layer (cushion layer), or a layer higher in elastic modulus than the polishing layer (highly elastic layer). The cushion layer is a member necessary for making both of the planarity and the uniformity, which have a tradeoff relationship therebetween, compatible with each other in CMP. The planarity denotes the flatness of a patterned portion obtained at the time of polishing a material to be polished having fine irregularities generated when the pattern is formed. The uniformity denotes the evenness of the whole of a material to be polished. The planarity is improved in accordance with properties of the polishing layer, and the uniformity is improved in accordance with properties of the cushion layer. The highly elastic layer is used to improve the polishing pad in planarizing property when the used polishing layer is soft in order to restrain the generation of scratches in CMP. The use of the highly elastic layer also makes it possible to restrain edges of the material to be polished from being excessively shaven.

Examples of the cushion layer include fiber non-woven fabrics such as a polyester non-woven fabric, a nylon non-woven fabric and an acrylic non-woven fabric; resin-impregnated non-woven fabrics such as a polyester non-woven fabric impregnated with polyurethane; polymeric resin foams such as a polyurethane foam and a polyethylene foam; rubbery resins such as butadiene rubber and isoprene rubber; and photosensitive resins.

Examples of the highly elastic layer include polyester films such as a polyethylene terephthalate film and a polyethylene naphthalate film; polyolefin films such as a polyethylene film and a polypropylene film; and nylon films.

<Step of Bonding Polishing Layer and Supporting Layer to Each Other with Adhesive Layer Interposed Therebetween>

The method for bonding the circular polishing sheet and the supporting layer to each other with the adhesive layer interposed therebetween is not particularly limited as far as it is a method of bonding the circular polishing sheet and the supporting layer to each other while these members are pressurized. The method is, for example, a method of laminating a hot-melt adhesive sheet onto the supporting layer (or the circular polishing sheet), heating the adhesive through a heater to be melted, laminating the circular polishing sheet (or the supporting layer) onto the melted adhesive, and then pressing the laminate. The pressing pressure is not particularly limited, and is from about 0.1 to 1.0 MPa.

Instead of the adhesive layer made of the hot-melt adhesive, a double-sided tape may be used. The double-sided tape may be a double-sided tape having an ordinary structure in which adhesive layers are provided, respectively, on both surfaces of a substrate. This substrate makes it possible to prevent the penetration of slurry into the supporting layer, and prevent the supporting layer and the adhesive from being peeled from each other.

Examples of the substrate include polyester films such as a polyethylene terephthalate film and a polyethylene naphthalate film; polyolefin films such as a polyethylene film and a polypropylene film; and nylon films. Among the films, it is preferred to use a polyester film which is excellent in property for preventing the penetration of water. The composition of the adhesive layer is, for example, that of a rubbery adhesive or acrylic adhesive.

The front surface of the substrate may be subjected to an easily bonding-attaining treatment such as corona treatment or plasma treatment.

The thickness of the substrate is not particularly limited, and is preferably from 10 to 180 μm from the viewpoint of transparency, flexibility, rigidity, and others.

When a double-sided tape is used, the thickness of the adhesive layer is preferably from 10 to 200 μm, more preferably from 30 to 100 μm.

In the layered circular polishing pad, a double-sided tape may be provided onto a surface thereof that is to be bonded to a platen.

Regarding the supporting layer and the double-sided tape, it is allowable to bond a supporting layer and a double-sided tape having the same size as the adhesive layer to the polishing layer, or to bond a supporting layer and a double-sided tape that are each in a sheet form to the polishing layer and subsequently cut the resultant into a size consistent with the size of the polishing layer.

### <Method for Producing Semiconductor Device>

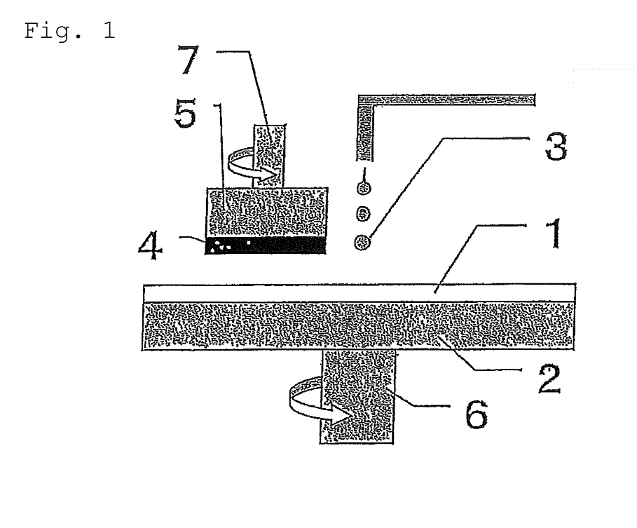

A semiconductor device is produced through the step of using the polishing pad to polish a surface of a semiconductor wafer. The semiconductor wafer is generally a member in which an interconnection metal and an oxide film are laminated onto a silicon wafer. The method and device for polishing the semiconductor wafer are not particularly limited. As illustrated in FIG. 1, the method is performed by use of, for example, a polishing apparatus equipped with a polishing platen 2 supporting a polishing pad 1, a support (polishing head) 5 holding a semiconductor wafer 4, a backing material for applying uniform pressure against the wafer and a supply mechanism of a polishing agent 3. The polishing pad 1 is mounted on the polishing platen 2 by attaching the pad to the platen with a double sided tape. The polishing platen 2 and the support 5 are disposed so that the polishing pad 1 and the semiconductor wafer 4 supported or held by the polishing platen 2 and the support 5, respectively, are opposite to each other. The polishing platen 2 and the support 5 are provided with respective rotary shafts 6 and 7. A pressure mechanism for pressing the semiconductor wafer 4 to the polishing pad 1 is installed on the support 5 side. During polishing, the semiconductor wafer 4 is polished by being pressed against the polishing pad 1 while the polishing platen 2 and the support 5 are rotated and a slurry is fed. A flow rate of the slurry, a polishing load, a polishing platen rotation number and a wafer rotation number are not particularly limited, and they are properly adjusted.

Through this process, the surface roughness of the surface of the semiconductor wafer 4 is improved so that scratches are removed. Thereafter, the wafer is subjected to dicing, bonding, packaging and other operations. In this way, a semiconductor device is produced. The semiconductor device is used for an arithmetic processing unit, a memory, and others. In the same way as described above, a glass substrate for a lens or a hard disc can be finish-polished.

### EXAMPLES

Hereinafter, the present invention will be described by way of examples. However, the present invention is not limited to these examples.

### [Measuring and Evaluating Methods]

### (Number-Average Molecular Weight)

A number-average molecular weight was measured by GPC (gel permeation chromatography) and a value as measured was converted in terms of standard polystyrene.

GPC device: LC-10A, manufactured by SHIMADZU CORPORATION.

Columns: the following three columns connected to each other are used: column (PLgel, 5 μm, 500 angstroms), column (PLgel, 5 μm, 100 angstroms), and column (PLgel, 5 μm, 50 angstroms) each manufactured by Polymer Laboratories Inc.

Flow rate: 1.0 mL/min.

Concentration: 1.0 g/L

Injected amount: 40 μL

Column temperature: 40° C.

Eluent: tetrahydrofuran

### (Average Cell Diameter)

A prepared polyurethane foam was cut with a microtome cutter to have parallel surfaces and to be made as thin as possible to give a thickness of 1 mm or less. The cut foam was used as a sample for measuring average cell diameter. The sample was fixed on a slide glass piece, and an SEM (S-3500N, manufactured by Hitachi Science Systems Ltd.) was used to observe the sample with 100 magnifications. In the resultant image, an image analyzing software (WinRoof, manufactured by Mitani Corp.) was used to measure the respective diameters of all cells in an arbitrary range of the image. The average cell diameter thereof was calculated.

### (Specific Gravity)

Measurement was conducted in accordance with JIS Z8807-1976. A prepared polyurethane foam was cut out into a rectangular form 4 cm×8.5 cm in size (thickness: arbitrary). The resultant cut foam was used as a sample for measuring specific gravity. The sample was allowed to stand still in an environment having a temperature of 23±2° C. and a humidity of 50±5% for 16 hours. The specific gravity was measured, using a gravimeter (manufactured by Sartorius Co., Ltd.).

### (Hardness)

Measurement was conducted in accordance with JIS K6253-1997. A prepared polyurethane foam was cut out into a piece having a size of 2 cm×2 cm (thickness: arbitrary). The resultant piece was used as a sample for measuring hardness. The sample was allowed to stand still in an environment having a temperature of 23±2° C. and a humidity of 50±5% for 16 hours. In the hardness measurement, samples were stuck on one another to a thickness of 6 mm or more. A hardness meter (Asker D hardness meter, manufactured by Kobunshi Keiki Co., Ltd.) was used to measure hardness.

### (Evaluation of Peel in Layered Polishing Pad)

A produced layered polishing pad was used to polish a tungsten wafer having a film thickness of 8000 angstroms under conditions described below for 60 hours, and then the layered polishing pad was observed with the naked eyes to check whether or not separation or peeling was generated between the layers. A polishing apparatus used was SPP600S (manufactured by Okamoto Machine Tool Works, Ltd.). Regarding the conditions for the polishing, as a slurry, an aqueous solution was used in which hydrogen peroxide was added in a proportion of 2% by weight to a diluted liquid obtained by diluting W2000 (manufactured by Cabot) two times with super pure water, and the aqueous solution was added at a flow rate of 150 mL/min while the wafer was polished. The polishing load, the rotation number of the polishing platen, and the rotation number of the wafer were set to 5 psi, 120 rpm, and 120 rpm, respectively. A dresser (M. type #100, manufactured by Asahi Diamond Industrial Co., Ltd.) was used to dress the front surface of the polishing layer for 20 seconds at predetermined intervals under conditions that the dressing load, the rotation number of the dresser, and the rotation number of the platen were set to 50 g/cm², 15 rpm, and 30 rpm, respectively.

◯): No separation or peeling is observed between layers.

X: Separation or peeling is observed between layers.

(Formation of polishing layer)

Into a polymerizing vessel were put 100 parts by weight of a polyether prepolymer (ADIPRENE L-325, manufactured by Uniroyal, Inc.; NCO concentration: 2.22 meq/g) and 3 parts by weight of a silicone surfactant (SH-192, manufactured by Dow Corning Toray Co., Ltd.). These components were mixed with each other. The mixture was adjusted to 80° C. and was defoamed under reduced pressure. Subsequently, the reaction system was vigorously stirred for about 4 minutes with a stirring blade at a rotational speed of 900 rpm so that air bubbles were incorporated into the reaction system. Thereto were added 26 parts by weight of 4,4′-methylenebis(o-chloroaniline) (IHARACUAMINE, manufactured by Ihara Chemical Industry Co., Ltd.), which was beforehand melted at a temperature of 120° C. Thereafter, this mixed liquid was stirred for 1 minute, and then cast into a pan-shaped open mold. The mold was put into an oven when the fluidity of this mixed liquid was lost. The resultant resin was post-cured at 80° C. for 12 hours to yield a polyurethane foam block. A slicer (VGW-125, manufactured by Amitec Corporation) was used to slice the polyurethane foam block, which was heated to about 80° C., so that a polyurethane foam sheet (average cell diameter: 50 μm, specific gravity: 0.86, hardness: 52 degrees) was yielded. Next, a buffing machine (manufactured by Amitec Corporation) was used to subject the sheet to surface-buffing treatment until the sheet had a thickness of 1.27 mm. In this way, a sheet which was adjusted in thickness precision was yielded. A grooving machine (manufactured by Techno Inc.) was used to form concentric grooves in the front surface of this buffed sheet to have a groove width of 0.25 mm, a groove pitch of 1.5 mm and a groove depth of 0.45 mm. An outer circumferential edge thereof was cut to adjust the width of a convex region of the outermost circumferential region into a value described in Table 1. In this way, a polishing layer having an outside diameter of about 61 cm was produced.

(Step of Bonding Polishing Layer and Supporting Layer to Each Other with Adhesive Layer Interposed Therebetween)

### Example 1

A laminator was used to bond a double-sided tape (#5782 PGW-A2, manufactured by Sekisui Chemical Co., Ltd.; substrate: polyester non-woven fabric; adhesive layer: acrylic adhesive; thickness: 60 μm; shear stress: 750 kPa) to a surface of the polishing layer that was opposite to the grooved surface thereof. Furthermore, a corona-treated cushion sheet (polyethylene foam, TORAY PEF, manufactured by Toray Industries, Inc.; thickness: 0.8 mm) was prepared, and the front surface thereof was subjected to buffing treatment. The laminator was used to bond this cushion sheet onto the double-sided tape. Furthermore, the laminator was used to bond the above-mentioned double-sided tape onto the other surface of the cushion sheet. The layers of the resultant that were different from the polishing layer (the double-sided tape+the cushion sheet+the double-sided tape) were cut to have a size consistent with the size of the polishing layer. In this way, a layered polishing pad was produced.

### Examples 2, 3 and Comparative Example 1

The same operations as in Example 1 were made except that the width of the convex region of the outermost circumferential region of the layered polishing pad was changed to a width described in Table 1.

### Comparative Example 2

The same operations as in Example 1 were made except that the shape of the outermost circumferential region of the layered polishing pad was made into the form of a concave.

TABLE 1

| | | | | Comparative | Comparative |
|---|---|---|---|---|---|
| | Example 1 | Example 2 | Example 3 | Example 1 | Example 2 |
| Width (mm) of convex | 2.0 | 1.0 | 0.75 | 0.5 | — |
| region of outermost | | | | | |
| circumferential region | | | | | |
| Evaluation | ◯ | ◯ | ◯ | X | X |

According to Table 1, in the polishing pad of each of Examples 1 to 3, no separation or peeling was observed between layers even after the polishing pad was used for long-term polishing.

### INDUSTRIAL APPLICABILITY

The method for producing a layered polishing pad of the present invention is usable as a method for producing a layered polishing pad which performs planarization of materials requiring a high surface planarity such as optical materials including a lens and a reflecting mirror, a silicon wafer, a glass substrate or aluminum substrate for a hard disc, and a product of general metal polishing.

### DESCRIPTION OF REFERENCE SIGNS

1: layered polishing pad
2: polishing platen
3: polishing agent (slurry)
4: material to be polished (semiconductor wafer)
5: support (polishing head)
6 and 7: rotary axes
8: circular polishing sheet
9: convex region of outermost circumferential region
10: grooves (concave portions)

1. A method for producing a layered circular polishing pad, comprising steps of: forming, in a circular polishing sheet, concentric grooves and an outer circumferential region having a width of ½ or more of a groove pitch of the concentric grooves; and bonding the circular polishing sheet and a supporting layer to each other with a bonding member interposed therebetween to produce a layered polishing sheet.

2. A layered circular polishing pad, produced by the method for producing a layered circular polishing pad according to claim 1.

3. A layered circular polishing pad, comprising a circular polishing layer and a supporting layer laminated over each other with an adhesive member interposed therebetween, wherein concentric grooves are formed in the polishing layer, the polishing layer has an outer circumferential region in which the concentric grooves are not formed, and the outer circumferential region has a width of ½ or more of a groove pitch of the concentric grooves.

4. A method for producing a semiconductor device, comprising the step of using the layered circular polishing pad according to claim 2 to polish a surface of a semiconductor wafer.

5. A method for producing a semiconductor device, comprising the step of using the layered circular polishing pad according to claim 3 to polish a surface of a semiconductor wafer.
